(19) United States
(12) Patent Application Publication
(10) Pub. No.: US 2009/0046503 A1
(43) Pub. Date: Feb. 19, 2009

(54) Enhanced Gated Diode Memory Cells

(76) Inventors: Wing Kin Luk, Chappaqua, NY (US); Robert Heath Dennard, Croton-on-Hudson, NY (US)

Correspondence Address: RYAN, MASON & LEWIS, LLP, 90 FOREST AVENUE, LOCUST VALLEY, NY, 11560, US

(21) Appl. No.: 11/840,658

(22) Filed: Aug. 17, 2007

(51) Int. Cl. G11C 11/36; H01L 21/329

(52) U.S. Cl. 365/175; 438/237; 257/E21.363

(57) ABSTRACT

A memory cell for use in an integrated circuit comprises a read transistor and a gated diode. The read transistor has a source terminal. The gated diode has a gate terminal in signal communication with the read transistor. A variable source voltage acts on the source terminal of the read transistor when the memory cell is in operation. The variable source voltage is temporarily altered when the memory cell is read. For example, the source voltage may be reduced when the read transistor is implemented using an N-type transistor and increased when the read transistor is implemented using P-type transistor. This acts to impart the memory cell with faster read speed, higher read margin, and lower standby current.

### CROSS REFERENCE TO RELATED APPLICATIONS

This application is related to an application by Luk et al., entitled “Gated Diode Memory Cells,” U.S. Patent Application Publication No. 2005/0128803 A1, having common inventors herewith, commonly assigned herewith, and incorporated by reference herein.

### FIELD OF THE INVENTION

The present invention is directed generally to semiconductor memories and, more particularly, to enhancements circuits for improving the performance of memory cells comprising gated diodes.

### BACKGROUND OF THE INVENTION

Memory cells comprising gated diodes (e.g., field effect transistor with an open source or drain terminal) may display operating characteristics substantially superior to memory cells based on other types of storage devices. Unlike capacitors, for example, gated diodes in memory cells can be configured to transfer some or all of their stored charge to the associated sensing circuitry (e.g., bitlines and sense amplifiers) during memory cell read operations rather than merely sharing the stored charge with this circuitry. This allows memory cells with gated diodes to demonstrate signal gains greater than one. In other words, the memory cell output voltage during a read operation may be greater than the voltage written into and stored in the memory cell.

FIG. 1 shows schematic diagrams of two variants of two-transistor, one-gated-diode (2T1D) memory cells: a single port 2T1D memory cell 100 (with a single bitline BL) and a dual port 2T1D memory cell 110 (with separate read and write bitlines, BLr and BLw, respectively). FIG. 2, moreover, shows dual port 2T1D memory cells incorporated into a memory array 200. In both the case of the single port memory cell and dual port memory cell designs, a single gated diode gd acts as a storage device within its respective memory cell. As a result, both memory cells may demonstrate signal gain greater than one during read operations. The output voltage of such memory cells for a stored state-1, Vcell_f, may, for example, under certain readily achieved operating configurations, be related to the voltage in the memory cell before the read operation, Vcell_i, by:

Vcell_{—}f/Vcell_{—}i=1+Ccell/Crg,

where Ccell is the on capacitance of the gated diode, and Crg is the capacitance of the read device transistor rg. The details of the structure, operational characteristics, and preferable operating configurations of such 2T1D memory cells are described in detail in U.S. patent application Ser. No. 10/735,061 (cited above).

A 2T1D memory cell demonstrating signal gain greater than one provides substantial advantages with respect to read margin when compared to other types of memory cells. Such a memory cell may, for example, easily achieve a read signal substantially higher than that of a two-transistor, one-capacitor (2T1C) memory cell. Nevertheless, even with these advantages, there is still a need for further refinements to 2T1D memory cell designs which allow these designs to achieve even better performance characteristics.

### SUMMARY OF THE INVENTION

Embodiments of the present invention address the above-identified need by providing enhancement circuits that act to dynamically modulate a source voltage acting on a read device transistor in a 2T1D memory cell. This, in turn, acts to impart the memory cell with better read speed, read margin, and standby current.

In accordance with an aspect of the invention, a memory cell for use in an integrated circuit comprises a read transistor and a gated diode. The read transistor has a source terminal. The gated diode has a gate terminal in signal communication with the read transistor. A variable source voltage acts on the source terminal of the read transistor when the memory cell is in operation. The variable source voltage is temporarily altered when the memory cell is read. For example, the source voltage may be reduced when the read transistor is implemented using an N-type transistor and increased when the read transistor is implemented using P-type transistor.

In accordance with one of the above-identified embodiments of the invention, a memory cell comprises a read device transistor, a gated diode, and a write device transistor that are arranged in a 2T1D memory cell configuration. This configuration acts to produce signal gain when the memory cell is read. Nevertheless, to even further improve the performance of this memory cell, a variable source voltage is applied to a source terminal of the read device transistor using specialized enhancement circuitry. This enhancement circuitry holds the source voltage high when the memory cell is either in a hold or write phase. In contrast, when the memory cell is being read, the enhancement circuitry reduces the source voltage to a lower potential, such as ground potential.

Keeping the source voltage high in the hold and write phases reduces standby leakage current in the read device transistor and consequently for the memory cells and the memory array. Dropping the source voltage during a read operation increases gate overdrive of the read device transistor, and, thereby, increases the read current through the read device transistor and causes the read speed to be enhanced.

These and other features and advantages of the present invention will become apparent from the following detailed description which is to be read in conjunction with the accompanying drawings.

### BRIEF DESCRIPTION OF THE DRAWINGS

FIG. 1 shows schematic diagrams of single port and dual port 2T1D memory cells.

FIG. 2 shows a schematic diagram of the FIG. 1 dual port 2T1D memory cell incorporated into a memory array.

FIG. 3 shows schematic diagrams of single port and dual port 2T1D memory cells in accordance with aspects of the invention.

FIGS. 4A and 4B show signal timing diagrams for the FIG. 3 memory cells.

FIG. 5 shows an illustrative enhancement circuit for the FIG. 3 memory cells arranged such that the memory cells share a common source voltage line.

FIGS. 6 and 7 show schematic diagrams and floorplans of the FIG. 3 dual port memory cell implemented in a memory array with global hold/read lines running in the wordline direction (row direction).

FIGS. 8 and 9 show schematic diagrams and floorplans of the FIG. 3 dual port memory cell implemented in memory arrays with partitioning in the bitline direction (column direction).

FIG. 10 shows schematic diagram and floorplan of the FIG. 5 dual port memory cell implemented in a memory array with partitioning in the bitline direction (column direction).

FIGS. 11A and 11B show simulated waveforms for the FIG. 10 memory array.

FIGS. 12 and 13 show the FIG. 5 dual port memory cell implemented in memory arrays with header transistors and shared header transistors, respectively.

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

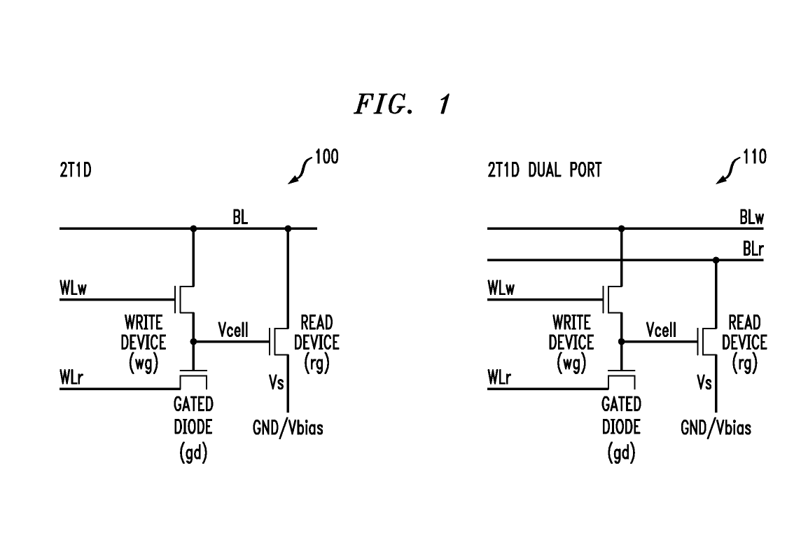

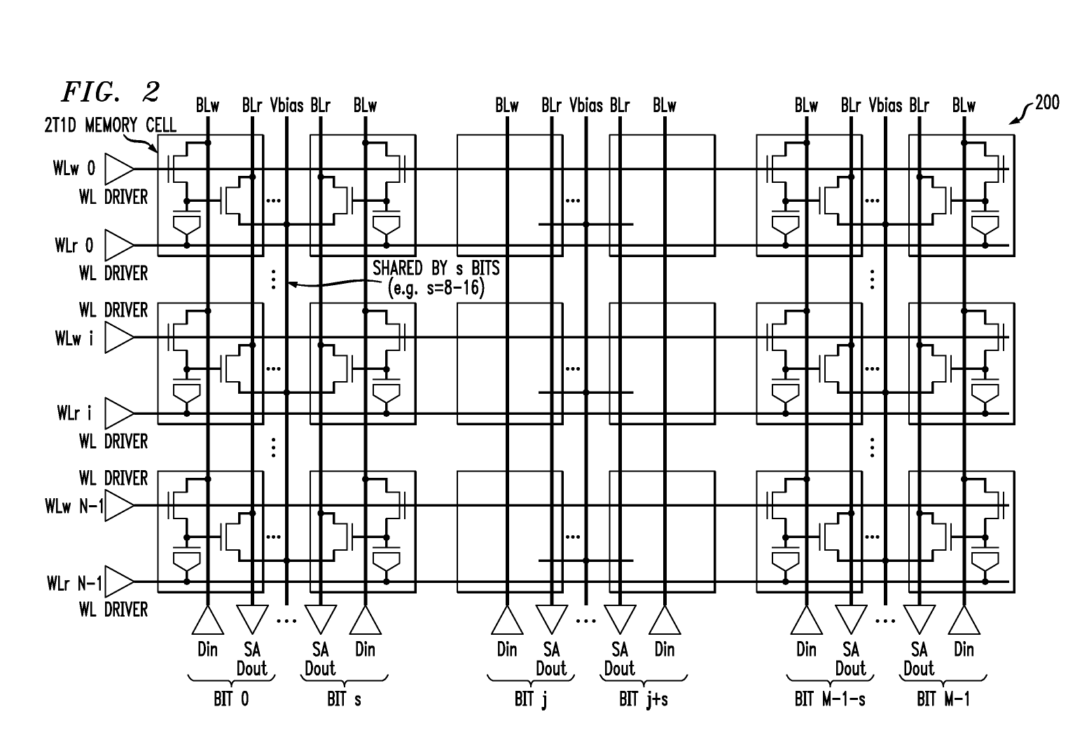

It will be observed that, in the 2T 1D memory cells 100, 110 shown in FIG. 1, no provision is made explicitly for dynamically changing the voltages on the source terminals (source voltages, Vs) of the read device transistors rg. In other words, Vs is held either at a given bias voltage, Vbias (e.g., 0.4 Volts (V) for 1-V silicon technology), or at ground voltage, GND (e.g., 0 V) (using high threshold voltage transistors for the read device transistors). Nevertheless, a constant Vs may not be ideal. Instead, several advantages may be obtained by temporarily (i.e., dynamically) changing Vs as a function of the operating phase of the memory cell. When a memory cell is selected and being read, temporarily lowering Vs (e.g., to GND) results in a larger gate overdrive on the read device transistor which, in turn, may lead to faster read speeds. In contrast, when the memory cell is not selected (i.e., in a hold phase) or selected for writing, it may be beneficial to set Vs back to a bias voltage higher than GND, or to some predetermined lower voltage, in order to fully switch off the read device transistor (rg) and thereby reduce standby leakage currents. Reducing standby leakage currents in this manner saves power and reduces the effect of the read device transistor on other memory cells that may share its bitline BL.

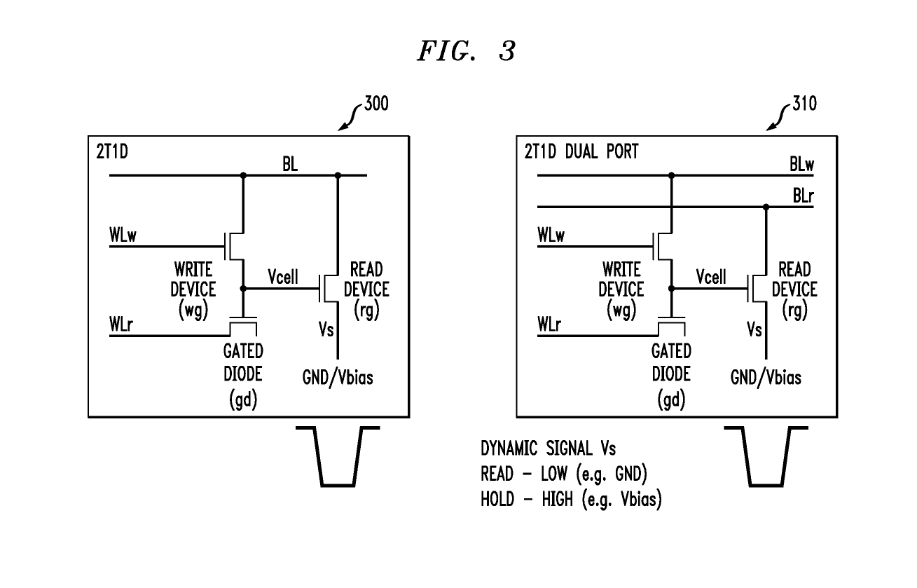

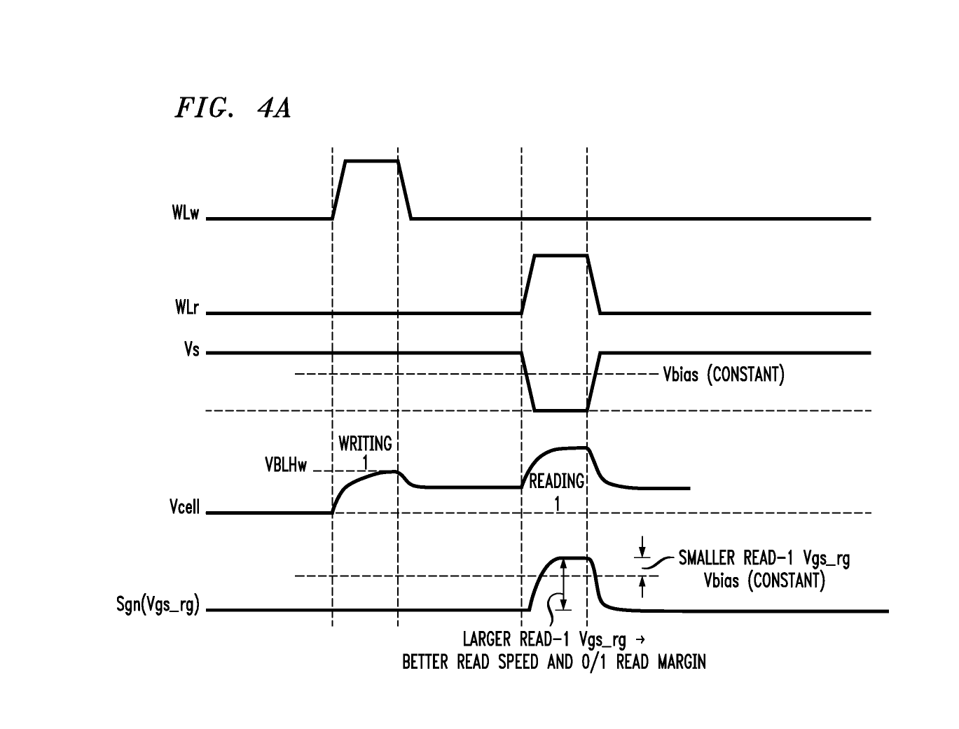

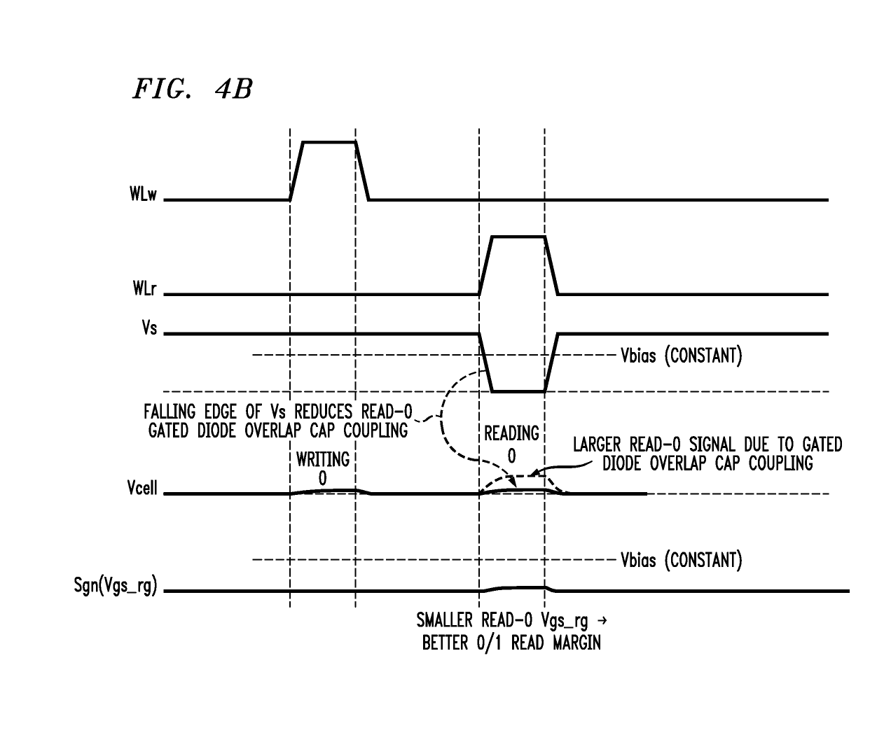

FIG. 3 shows a single port memory cell embodiment 300 and a dual port memory cell embodiment 310 in accordance with aspects of the invention. As indicated on the figure, Vs is temporarily lowered in both devices from Vbias to GND during read operations in order to achieve the above-described benefits. These dynamic changes to Vs have several effects on the read characteristics of the memory cells, which may be observed in FIGS. 4A and 4B. FIG. 4A, for example, shows a signal timing diagram that illustrates how a state-1 is written to and read from a 2T1D memory cell like those shown in FIG. 3. Writing a state-1 to the memory cell is accomplished in largely a conventional manner, namely, by temporarily setting the write wordline WLw high (e.g., 1.2 V for 1-V silicon technology) to turn on the write device transistor wg and simultaneously placing a high voltage, VBLHw (e.g., 0.4 Volts for 1-V silicon technology), on the bitline BL (or BLw in the case of the dual port memory cell). The bitline voltage is in turn written into the memory cell as the cell voltage Vcell. VBLHw is preferably higher than the threshold voltage of the associated gated diode gd, Vt_gd. As a result, this operation acts to turn the gated diode on as well as to cause a substantial amount of charge to be stored in the gated diode's inversion layer. The gated diode thereby behaves in some respects like a large storage capacitor.

It is noted that the memory cells 300, 310 use N-type transistors. Nevertheless, for the case of P-type transistors or mixed N- and P-type transistors, the approach can be extended accordingly. In such situations, the transistors and voltages will be implemented in the corresponding complementary form.

Vbias of the memory cell during hold and writing phases is preferably set so:

Vbias [symbol] Vcell_hold_max,

where Vcell_hold_max is the maximum voltage of Vcell while the memory cell is in hold or write phases. When storing a state-1, Vcell_hold_max is about VBLHw. Therefore, setting Vbias to VBLHw during hold and write phases will assure that the differential gate-source voltage on the gate terminal with respect to the source terminal of the read device transistor, Vgs_rg, is about zero when the memory cell not being read. This, of course, assures that the read device transistor is fully turned off and that standby leakage is minimized.

Reading the state of the memory cell in FIG. 4A is, in turn, accomplished by temporarily setting the read wordline WLr high and, in accordance with aspects of the invention, also temporarily setting Vs to GND. As indicated in FIG. 3, WLr acts on the source terminal of the gated diode gd. Therefore increasing WLr acts to reduce the voltage difference between Vcell and WLr which is connected to the source terminal of the gated diode (i.e., the differential voltage between the voltage acting on the gate terminal of the gated diode and the voltage acting on the source terminal of the gated diode) and, when this difference drops below Vt_gd, the gated diode is turned off. As this occurs, the charge stored in the gated diode is released to those devices attached to the gate terminal of the diode. More specifically, for reading a state-1 in the memory cell, Vcell temporarily increases to a boosted Vcell value, Vcell_boost(1), and the read device transistor rg is turned on, discharging the precharged high bitline. The change in the bitline voltage can be detected by using a sense amplifier.

Let Sgn(Vgs_rg) be the positive portion of the gate to source voltage of the read device transistor rg, which is the difference between Vcell and Vs. The voltages Vcell, Vs, and Sgn(Vgs_rg) for writing and reading state-1 are shown in FIG. 4A. Sgn(Vgs_rg) determines the gate overdrive acting on the read device. With Vs being temporarily at GND using the dynamic Vs scheme (DVS) during the read phase, the gate overdrive for the read device for a stored state-1, Vgs_rg_od_DVS(1), is:

Vgs_{—}rg_{—}od_DVS(1)=Vcell_boost(1)−Vt_{—}rg,

where Vt_rg is the threshold voltage of the read device transistor rg. In contrast, if Vs were held constant at Vbias=VBLHw instead of being reduced in the dynamic manner described herein, the overdrive, Vgs_rg_od_Vbias(1), would only be:

Vgs_{—}rg_{—}od_{—}Vbias(1)=Vcell_boost(1)−Vt_{—}rg−Vbias=Vcell_boost(1)−Vt_{—}rg−VBLHw.

Thus, these relations make it clear that the gate overdrive is higher (by an amount of about VBLHw) when Vbias is dynamically reduced (using the DVS scheme) than when it is left high at a constant Vbias. Such a difference in the overdrive is illustrated in FIG. 4A by the large magnitude of signal Sgn(Vgs_rg) compared to the small read-1 Vgs_rs using a constant Vbias. In fact, Vcell_boost_DVS(1) may be 2-3 times higher than VBLHw. The read margin and speed of a read-1 operation are thereby substantially enhanced.

FIG. 4B shows a timing diagram similar to FIG. 4A, but in this case, for writing and reading a state-0. As indicated in the figure, writing occurs by setting WLw high and leaving the write bitline BL (or BLw) low. With this input, Vcell is left low and the gated diode gd does not store any substantial charge. Subsequently, when reading the memory cell, WLr is set high and Vs is again temporarily dropped to GND. Vcell does not substantially rise and the read device transistor rg is not turned on. This, of course, causes minimal change to the voltage on the associated bitline and can be distinguished readily by a sense amplifier compared to the case of state-1, clearly acting to indicate a stored state-0.

As shown in FIG. 4B, the falling edge of Vs during a read operation gives an additional benefit that improves the read margin between reading a state-1 and a state-0. As Vs is pulled down while reading a state-0, the gate to source capacitance of the read device transistor, Cgs_rg, produces a coupling effect that pulls down the gate voltage of the read device transistor rg. Simultaneously, the gated diode's overlap capacitance between gate and the source, Cgd_ov, produces a coupling effect that acts to pull up the gate voltage of the read device transistor. These two coupling effects appear to cancel each other as the two capacitances are about the same, and the two pulses for Vbias and WLr are of about the same order of magnitude. The cancellation of the two effects results in a smaller Vcell at the gate terminal of the read device transistor (refer to the smaller Vcell waveform of FIG. 4B during “reading 0”) than that which would be present if Vs had been left at Vbias while reading (refer to the bigger Vcell waveform of FIG. 4B during “reading 0”). As a result, read margin, defined as the difference between Vcell(1) and Vcell(0), is even further increased.

Excluding the enhancement circuitry necessary to dynamically modulate Vs in the manner indicated above, the support circuitry required to read and write to the memory cells 300, 310 is largely conventional. This support circuitry would comprise, for example, row and column select circuitry, wordline drivers, bitline drivers, and sense amplifiers SA. Because these support circuits are conventional and would be well known to one skilled in the art, they are not further detailed herein. However, because the enhancement circuitry necessary to dynamically modulate Vs (hereinafterjust “enhancement circuitry”) is novel, several illustrative embodiments of this circuitry are detailed below. Of course, these illustrative embodiments are merely exemplary and modifications could be made to them and come within the scope of the invention.

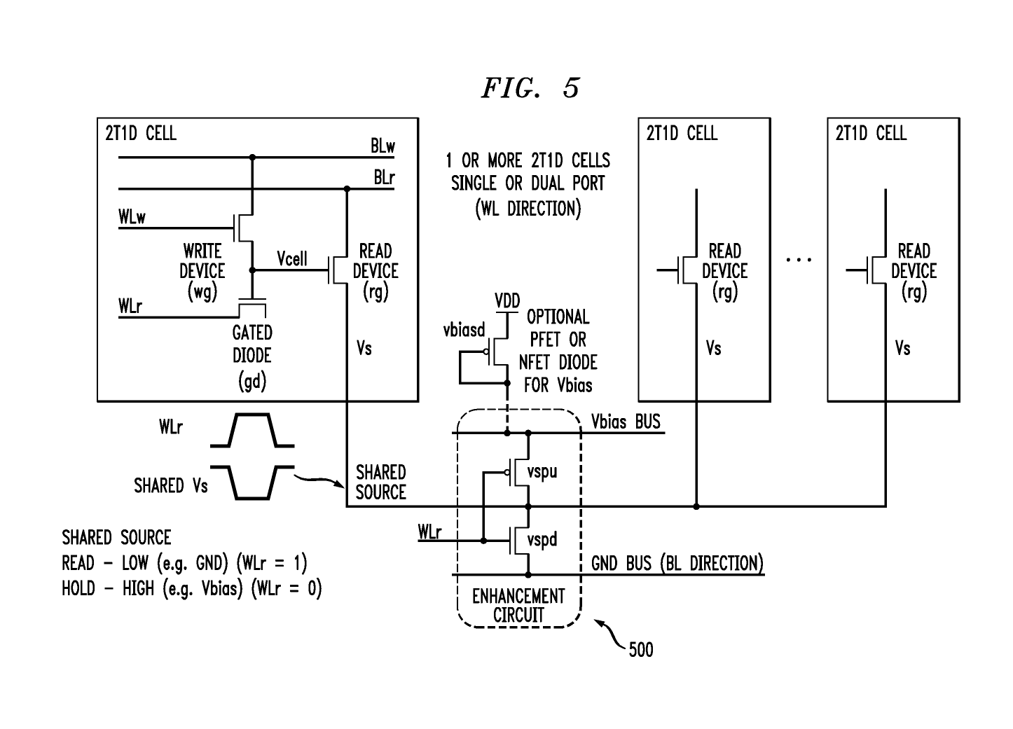

FIG. 5, for example, shows an illustrative enhancement circuit 500 for use with the 2T1D memory cells 300, 310 shown in FIG. 3. With this enhancement circuit, the source terminal of one or more read device transistors rg are connected together in a single shared source node SSrc. This node is connected to a pulldown NFET vspd and a pullup PFET vspu as shown in the figure. The gate terminals of the pulldown NFET and pullup PFET are connected to WLr, while a source/drain terminal of the pulldown NFET is attached to a GND bus and a source/drain terminal of the pullup PFET is attached to a Vbias bus. It will be observed that this circuitry essentially forms an inverter with WLr as the input and Vs as the output. When WLr goes high (indicating that the memory cell is in a read phase), the pulldown NFET pulls the shared source node down to GND. When WLr is low (indicating that a connected memory cell is in hold/write phase), the pullup PFET maintains the shared source node at Vbias. This enhancement circuit thereby accomplishes the dynamic Vs modulation described above with regard to FIGS. 4A and 4B.

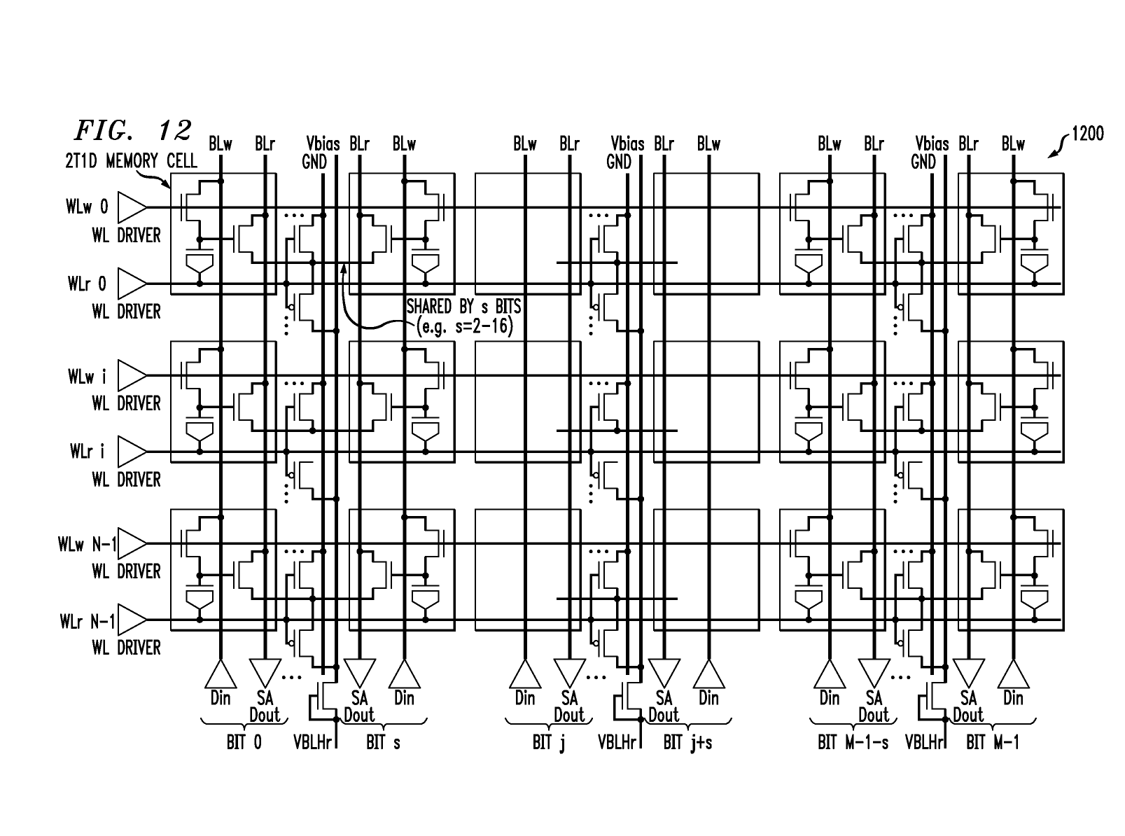

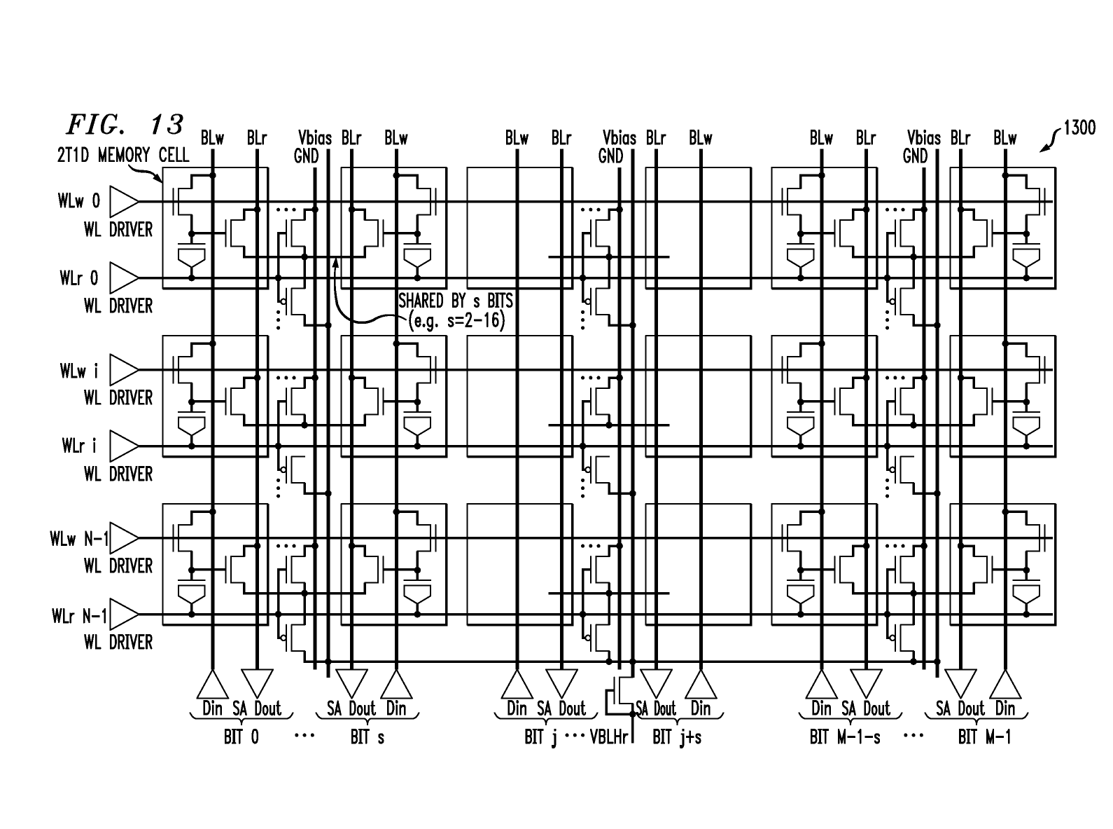

The source of the Vbias voltage for the enhancement circuit 500 may optionally be derived from a supply voltage VDD through a diode, Vbiasd, using either a PFET with gate terminal and drain terminal connected, or an NFET with gate terminal and drain terminal complementarily connected. The voltage drop across the diode is preferably about the threshold voltage of the diode, Vt_vbiasd. Moreover, Vt_vbiasd and the threshold voltage of the pullup PFET, Vt_vspu, are preferably chosen to be relatively high (e.g., 0.4 V for 1-V silicon technology) in order limit standby current of the memory array, as their performance is not critical. A single diode can be the source of Vbias for a single enhancement circuit (as shown in FIG. 12, for example), or for more than one enhancement circuit (as shown in FIG. 13, for example).

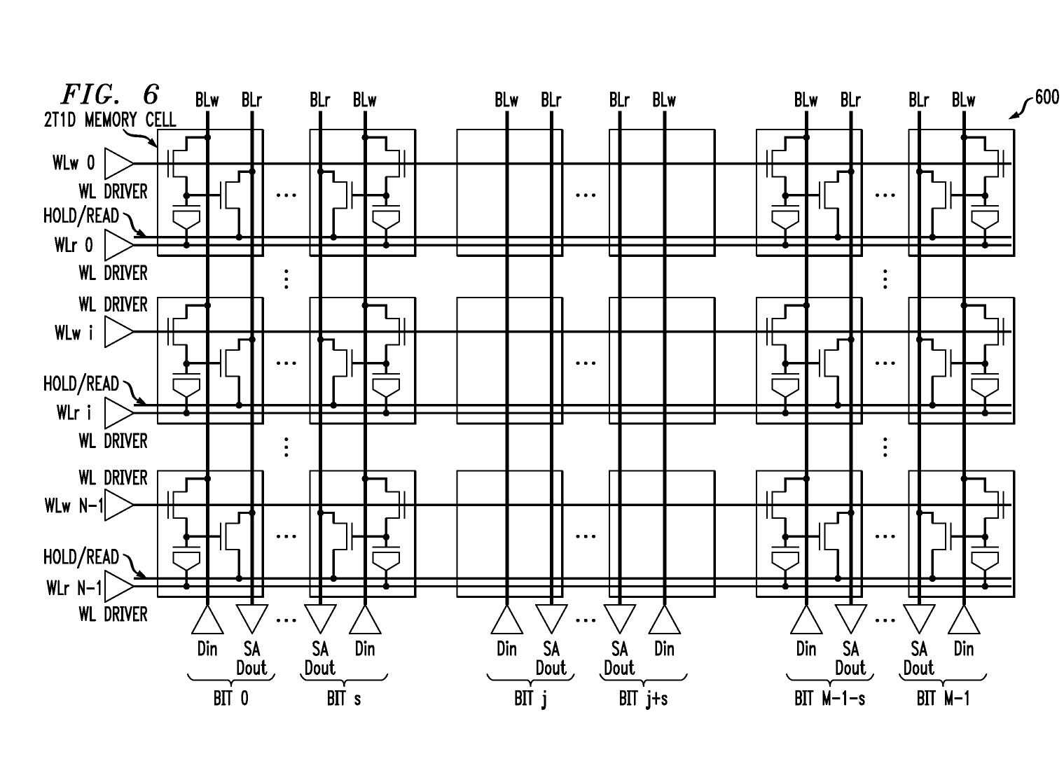

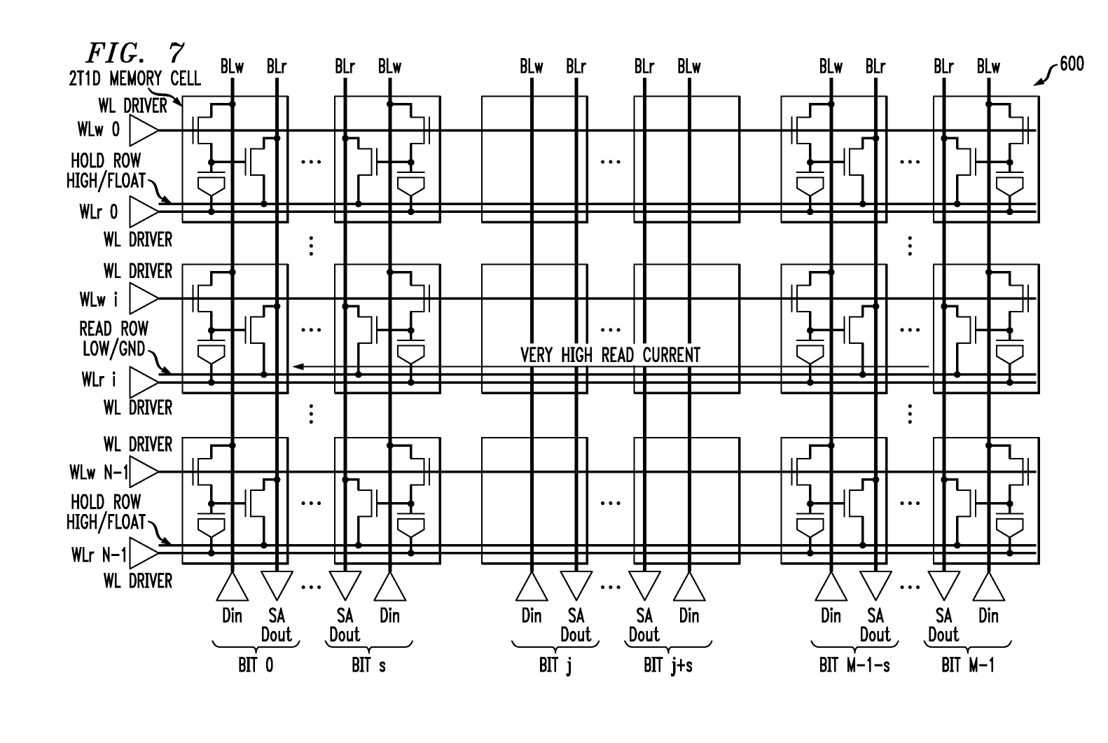

FIG. 6 shows a schematic diagram of 2T1D memory cells (in this case, dual port type) in a memory array 600 that utilizes global hold/read lines that run horizontally through the memory array. The hold/read lines are tasked with setting Vs in memory cells that are presently in a hold/write phase to a high state (e.g., VBLHw) or a floating condition, and to set Vs in memory cells presently in a read phase to a low state (e.g., GND). It should be noted, however, that the current in these hold/read lines for a row of memory cells selected for reading may be relatively high, as indicated in FIG. 7. The worst case would occur if all the memory cells in a selected row stored a state-1. In this case, the current on the hold/read line for this row may be equal the sum of all the bitline currents achieved when reading a state-1 from all selected memory cells in the row. If there are, for example, N selected cells in a row that store a state-1, then the total charge to be removed from the bitlines for reading these memory cells, Qread_row, would be:

Qread_row=N×CBL×VBLHr,

where CBL is the bitline capacitance, and VBLHr is the read bitline high voltage. Typical N in an array may be as high as 64, 128, or even 4K.

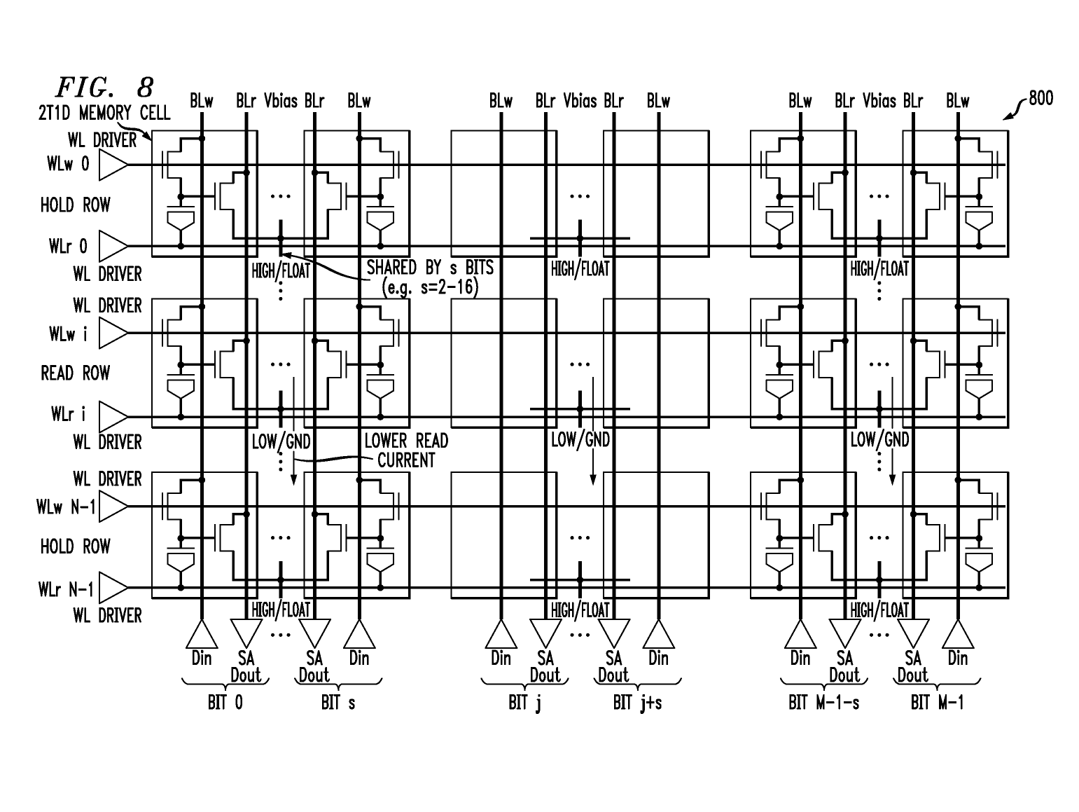

As a result, it may be preferable to partition the global hold/read lines column-wise and to localize the current return paths (i.e., the paths through the enhancement circuits to GND) for the source terminals of the read device transistors rg, as shown in the memory array 800 in FIG. 8. This allows the number of bitlines and, therefore, the total current acting on any single return path to be reduced to a manageable current density. For example, every 2 to 16 read transistors in a row may be connected together to form a partitioned group with its own enhancement circuit and return path. In such case, N is limited to between 2-16 for the total charge N×CBL×VBLHr, and hence is more manageable.

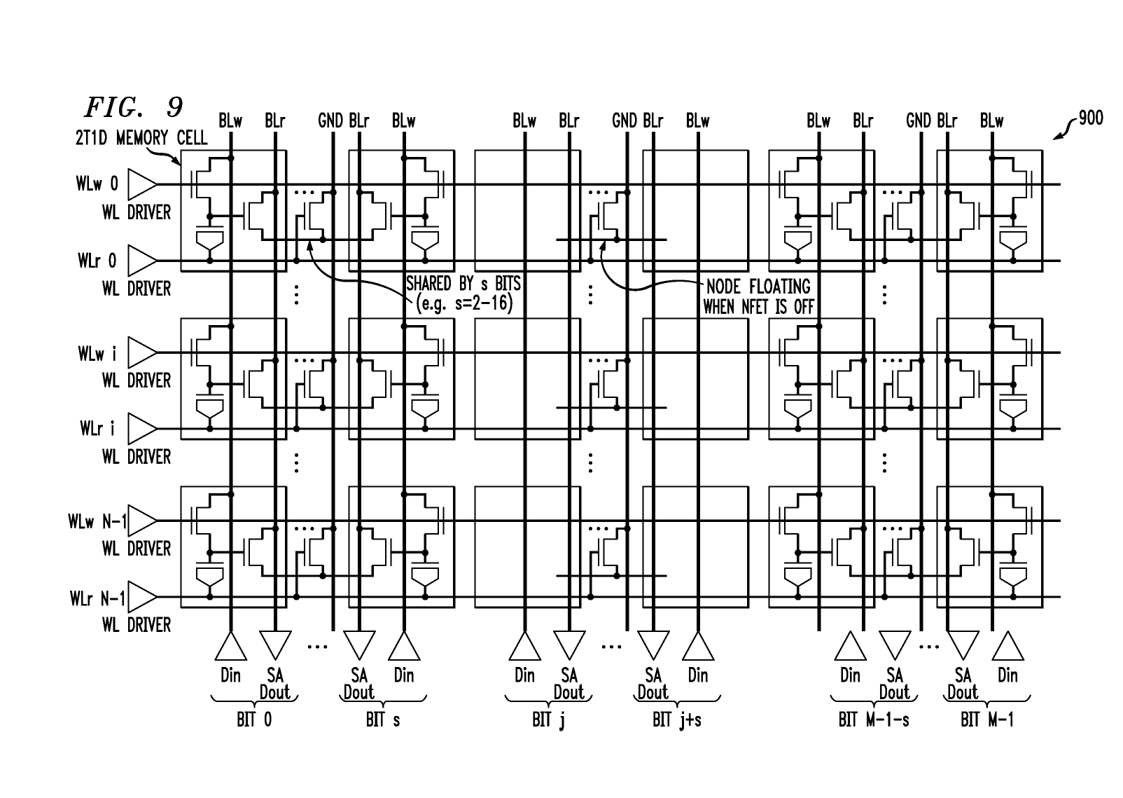

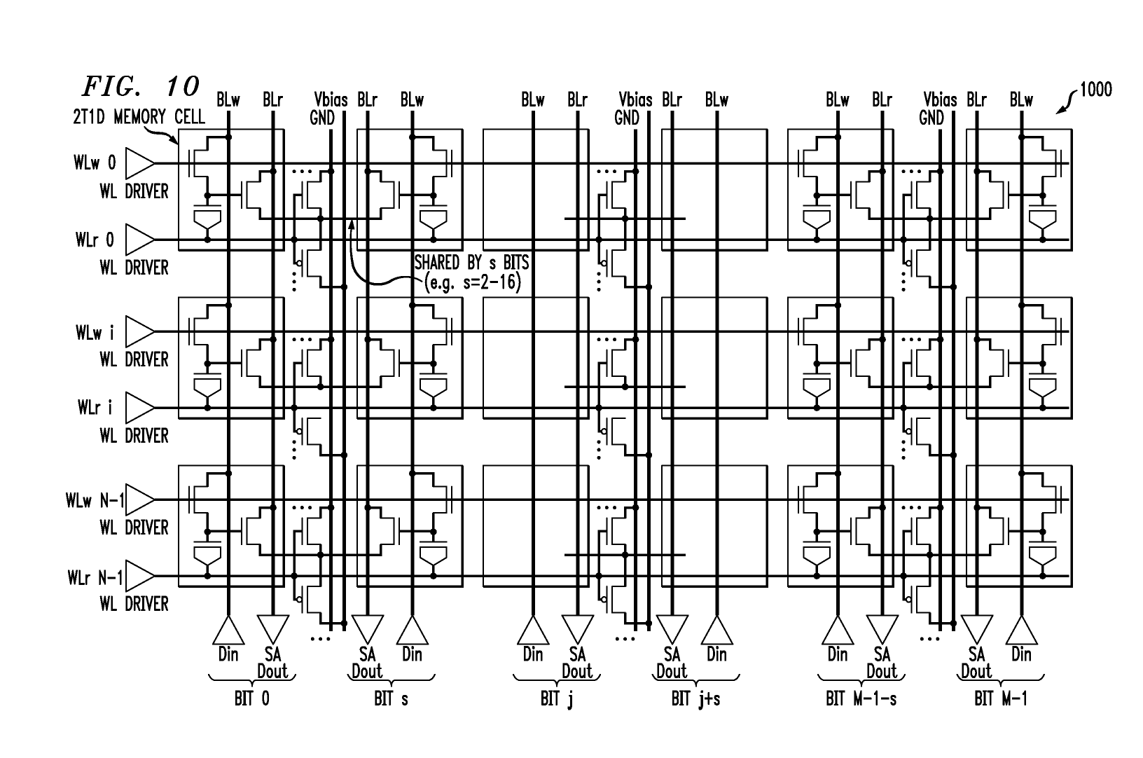

FIGS. 9 and 10 show two illustrative methods for accomplishing this type of partitioning. FIG. 9 shows a schematic diagram and floorplan of a memory array 900 in which memory cells in a given partitioned group may be dynamically set to a floating state or pulled down to GND depending on whether the memory cells are in a hold/write phase or in a read phase. The total of number of read devices in any partitioned group is 2 to 16. As shown, the source terminals of the read device transistors rg of the memory cells in a given partitioned group are connected to a pulldown NFET. When WLr for the partitioned group goes high, the NFET is turned on and Vs of the connected read devices is pulled down to GND. When WLr goes low (hold/write phase), Vs is allowed to float.

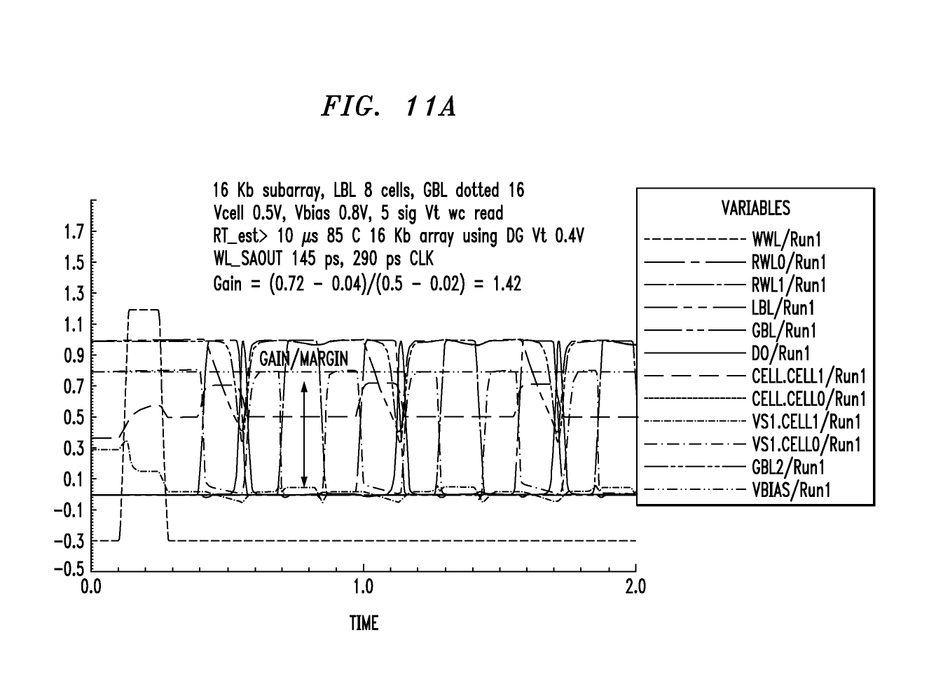

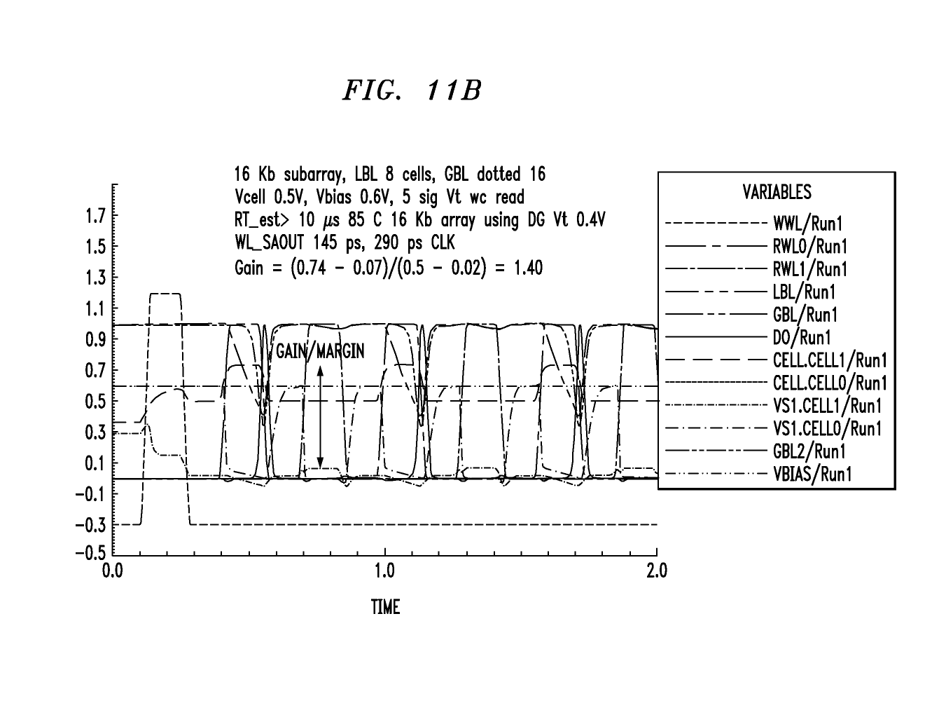

Alternatively, FIG. 10 shows a combination of a pulldown NFET and a pullup PFET may be used to set Vs in a partitioned group, thereby implementing enhancement circuits like that shown in FIG. 5 (i.e., an enhancement circuit using an inverter arrangement). Such an illustrative memory array 1000 has the advantage of setting Vs to a known value during hold and write phases rather than allowing it to float. FIGS. 11A and 11B show simulated waveforms for a memory array like the memory array 1000. It can be seen from the simulations that the combination of pullup NFET and pulldown PFET acts to set Vs to GND when WLr goes high (partitioned group is in a read phase) and to set Vs to Vbias when WLr is set low (partitioned group is in a hold/write phase). The combination of pulldown NFET and pullup PFET thereby accomplish the tasks of dynamically modulating Vs for the partitioned memory cells in accordance with aspects of the invention.

Optionally, as shown in a memory array 1200 in FIG. 12, a header transistor (e.g., an NFET with its gate terminal and drain terminal shorted together) acting as a diode may be added to the FIG. 10 enhancement circuitry between Vbias and the supply voltage VDD, thereby forming a current limiting source for the read device transistors rg of the memory array 1000. With such a design, a lower Vbias reduces standby leakage and a higher Vbias reduces the coupling noise for reading a state-0. Therefore, the proper choice for Vbias becomes a trade-off between power consumption and read margin. When the voltage drop across the header transistor is about the threshold voltage of the header transistor, Vt_header, it may be preferably to set Vbias such that:

Vbias≈VBLHr−Vt_header.

It should be noted that it is not necessary to have one header transistor per return path as shown in FIG. 12. Instead, a number of return paths (i.e., partitioned groups) may share a single diode as shown in a memory array 1300 in FIG. 13.

It should also be noted that the memory cells and memory arrays described above are part of the design for an integrated circuit chip. The chip design is created in a graphical computer programming language, and is stored in a computer storage medium (such as a disk, tape, physical hard drive or virtual hard drive such as in a storage access network). If the designer does not fabricate chips or photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are formed on a wafer. The photolithographic masks are utilized to define areas of the wafer (and/or the layers thereon) to be etched or otherwise processed.

The resulting integrated circuit chips may be distributed by the fabricator in raw wafer form (i.e., as a single wafer that has multiple unpackaged chips), as a bare die, or in packaged form. In the latter case, the chip is mounted in a single chip package (e.g., plastic carrier with leads that are affixed to a motherboard or other higher level carrier) or in a multichip package (e.g., ceramic carrier that has either or both surface interconnections or buried interconnections). In any case, the chip is then integrated with other chips, discrete circuit elements, and/or other signal processing devices as part of either an intermediate product (e.g., motherboard) or an end product. The end product may be any product that includes integrated circuit chips, ranging from toys and other low-end applications to advanced computer products having a display, a keyboard or other input device, and a central processor.

Although illustrative embodiments of the present invention have been described herein with reference to the accompanying figures, it is to be understood that the invention is not limited to those precise embodiments, and that various other changes and modifications may be made to these embodiments by one skilled in the art without departing from the scope of the appended claims.

What is claimed is:

1. A memory cell for use in an integrated circuit, the memory cell comprising:
a read transistor, the read transistor having a source terminal; and
a gated diode, the gated diode having a gate terminal in signal communication with the read transistor;
wherein a variable source voltage acts on the source terminal of the read transistor when the memory cell is in operation, the variable source voltage being temporarily altered when the memory cell is read.

2. The memory cell of claim 1, wherein the gated diode forms a storage cell in the memory cell.

3. The memory cell of claim 1, wherein the gated diode comprises a transistor with a source terminal or a drain terminal that is electrically open.

4. The memory cell of claim 1, wherein the gate terminal of the gated diode is in signal communication with a gate terminal of the read transistor.

5. The memory cell of claim 1, wherein the memory cell further comprises a write transistor, a terminal of the write transistor being in signal communication with a gate terminal of the read transistor and the gate terminal of the gated diode.

6. The memory cell of claim 1, wherein the variable source voltage acts to modify the read margin of the memory cell.

7. The memory cell of claim 1, wherein the variable source voltage acts to modify the standby current of the memory cell.

8. The memory cell of claim 1, wherein the variable source voltage is temporarily reduced when the memory cell is being read.

9. The memory cell of claim 1, wherein the variable source voltage is temporarily reduced to about ground potential for the memory cell when the memory cell is being read.

10. The memory cell of claim 1, wherein the variable source voltage, when not reading from the memory cell, is set to a voltage at least equal to a write voltage applied to a bitline when writing a state-1 to the memory cell.

11. An integrated circuit comprising a plurality of memory cells, at least one of the plurality of memory cells comprising:
a read transistor, the read transistor having a source terminal; and
a gated diode, the gated diode having a gate terminal in signal communication with the read transistor;
wherein a variable source voltage acts on the source terminal of the read transistor when the memory cell is in operation, the variable source voltage being temporarily altered when the memory cell is read.

12. The integrated circuit of claim 11, further comprising an enhancement circuit operative to temporarily alter the variable source voltage acting on the source terminal of the read transistor when the memory cell is read.

13. The integrated circuit of claim 12, wherein the enhancement circuit comprises at least one of a pullup transistor and a pulldown transistor.

14. The integrated circuit of claim 12, wherein the enhancement circuit comprises an inverter.

15. The integrated circuit of claim 12, wherein the enhancement circuit is at least partially controlled by a signal on a wordline.

16. The integrated circuit of claim 11, wherein the at least one of the plurality memory cells comprises two or more memory cells, the two or more memory cells being partitioned into a plurality of groups, each of the groups having a respective enhancement circuit operative to temporarily alter the variable source voltage acting on the source terminals of the memory cells making up the respective group when these memory cells are being read.

17. The integrated circuit of claim 11, further comprising a header transistor operative to limit current flow through the read transistor.

18. The integrated circuit of claim 17, wherein the header transistor comprises a transistor with a gate terminal and a drain terminal, the gate terminal being electrically connected to the drain terminal.

19. The integrated circuit of claim 11, wherein the gate terminal of the gated diode is in signal communication with a gate terminal of the read transistor.

20. The integrated circuit of claim 11, wherein the variable source voltage is temporarily reduced when the memory cell is being read.

21. The integrated circuit of claim 1, wherein the variable source voltage is temporarily reduced to about ground potential for the memory cell when the memory cell is being read.

22. A method of forming a memory cell for use in an integrated circuit, the method comprising the steps of:
forming a read transistor, the read transistor having a source terminal; and
forming a gated diode, the gated diode having a gate terminal in signal communication with the read transistor;
wherein a variable source voltage acts on the source terminal of the read transistor when the memory cell is in operation, the variable source voltage being temporarily altered when the memory cell is read.
